(19) United States
(12) Patent Application Publication
(10) Pub. No.: US 2025/0318446 A1
(43) Pub. Date: Oct. 9, 2025

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Seung Yun LEE, Icheon-si (KR); Tae Hoon KIM, Icheon-si (KR)

(21) Appl. No.: 18/826,675

(22) Filed: Sep. 6, 2024

(30) Foreign Application Priority Data
Apr. 4, 2024 (KR) 10-2024-0045722

(51) Int. Cl. H10N 70/00; H10B 63/00

(52) U.S. Cl. CPC H10N 70/063; H10B 63/00; H10N 70/066; H10N 70/821; H10N 70/841; H10N 70/882

(57) ABSTRACT

A semiconductor device may include a row line, a first column line crossing the row line, a second column line crossing the row line, a first memory cell positioned between the row line and the first column line and including a first variable resistance pattern adjacent to the first column line and a first switching pattern adjacent to the row line, and a second memory cell positioned between the row line and the second column line and including a second variable resistance pattern adjacent to the row line and a second switching pattern adjacent to the second column line.

### CROSS-REFERENCE TO RELATED APPLICATION

This application claims priority under 35 U.S.C. § 119 to Korean Patent Application No. 10-2024-0045722 filed on Apr. 4, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a row line, a first column line crossing the row line, a second column line crossing the row line, a first memory cell positioned between the row line and the first column line, and including a first variable resistance pattern adjacent to the first column line and a first switching pattern adjacent to the row line, and a second memory cell positioned between the row line and the second column line, and including a second variable resistance pattern adjacent to the row line and a second switching pattern adjacent to the second column line.

According to an embodiment of the present disclosure, a semiconductor device may include row lines, column lines crossing the row lines, and memory cells positioned between the row lines and the column lines and including first memory cells and second memory cells. Each of the first memory cells may include a first variable resistance pattern and a first switching pattern on the first variable resistance pattern, and each of the second memory cells may include a second switching pattern and a second variable resistance pattern on the second switching pattern.

According to an embodiment of the present disclosure, a method of manufacturing a semiconductor device may include forming first variable resistance patterns and second variable resistance patterns alternately arranged along a first direction and a second direction crossing the first direction, forming a first mask pattern that covers the second variable resistance patterns and includes openings over the first variable resistance patterns, and forming first switching patterns by injecting ions selectively into the first variable resistance patterns.

According to an embodiment of the present disclosure, a method of manufacturing a semiconductor device may include forming a first variable resistance layer, forming a second variable resistance layer on the first variable resistance layer, forming second variable resistance lines by etching the second variable resistance layer, forming first variable resistance lines by etching the first variable resistance layer, forming first variable resistance patterns and second variable resistance patterns that are alternately arranged in a first direction and a second direction crossing the first direction by etching the second variable resistance lines, forming first switching patterns by injecting ions selectively into the second variable resistance patterns, forming third variable resistance patterns and fourth variable resistance patterns by etching the first variable resistance lines, and forming second switching patterns by injecting the ions selectively into the third variable resistance patterns.

### BRIEF DESCRIPTION OF THE DRAWINGS

FIGS. 1A, 1B, and 1C are diagrams illustrating a semiconductor device according to an embodiment of the present disclosure.

FIGS. 2A and 2B are diagrams illustrating a semiconductor device according to an embodiment of the present disclosure.

FIGS. 3A, 3B, 4A, 4B, 5A, 5B, 6A, 6B, 7A, 7B, 8A, 8B, 9A, and 9B are diagrams illustrating a method of manufacturing a semiconductor device according to an embodiment of the present disclosure.

FIGS. 10A, 10B, 11A, 11B, 12A, 12B, 13A, 13B, 14A, and 14B are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided.

Hereinafter, some embodiments according to of the present disclosure are described with reference to the accompanying drawings.

As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C indicates A or B or C or AB or AC or BC or ABC (i.e., A and B and C).

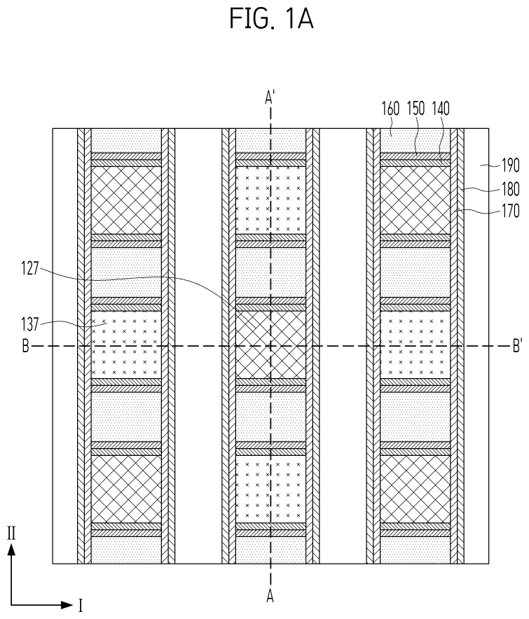

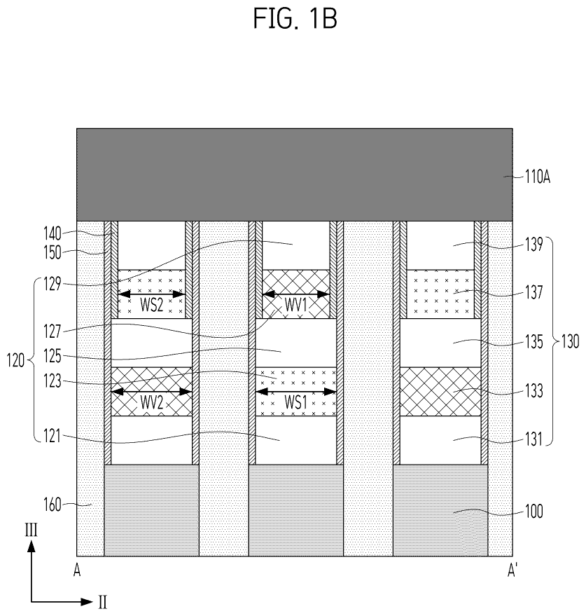

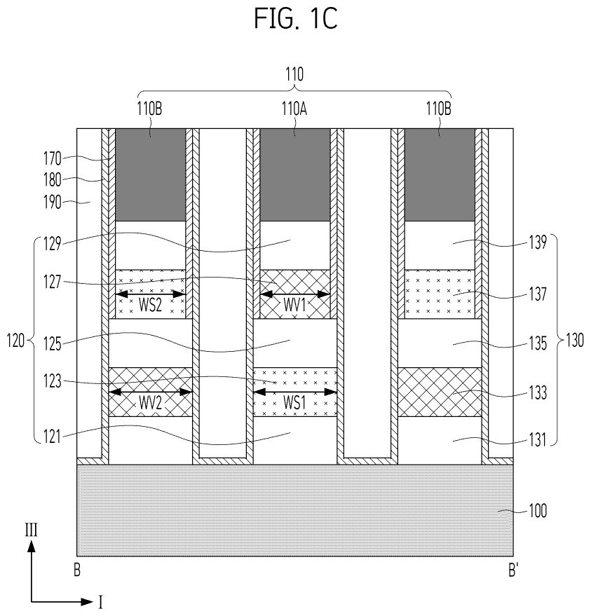

FIGS. 1A to 1C are diagrams illustrating a semiconductor device according to an embodiment of the present disclosure. FIG. 1A may be a plan view, FIG. 1B may be a cross-sectional view taken along line A-A′ of FIG. 1A, and FIG. 1B may be a cross-sectional view taken along line B-B′ of FIG. 1A.

Referring to FIGS. 1A to 1C, the semiconductor device may include row lines 100, column lines 110, first memory cells 120, second memory cells 130, first liner layers 140, second liner layers 150, first gap fill layers 160, third liner layers 170, fourth liner layers 180, or second gap fill layers 190, or may include a combination thereof.

Each of the row lines 100 may extend in a first direction I. The row lines 100 may be positioned to be spaced apart from each other in a second direction II crossing the first direction I. The column lines 110 may be positioned on the row lines 100 and may cross the row lines 100. For example, each of the column lines 110 may extend in the second direction II and the column lines 110 may be positioned to be spaced apart from each other in the first direction I. The column lines 110 may include a first column line 110A or a second column line 110B. The first column line 110A may cross the row line 100, and the second column line 110B may cross the row line 100. The first column line 110A and the second column line 110B may be alternately arranged. For example, the first column line 110A may be positioned between the second column lines 110B. Here, the row line 100 or the column line 110 may be a word line or a bit line. For example, the row line 100 may be the word line, and the column line 110 may be the bit line. As another example, the row line 100 may be the bit line, and the column line 110 may be the word line. The row line 110 or the column line 110 may include a conductive material such as tungsten.

The first memory cells 120 and the second memory cells 130 may be positioned between the row lines 100 and the column lines 110. The first memory cell 120 may be positioned between the row line 100 and the first column line 110A, and the second memory cell 130 may be positioned between the row line 100 and the second column line 110B. The memory cells 120 and 130 may be alternately arranged in the first direction I and the second direction II. For example, the first memory cells 120 and the second memory cells 130 may be arranged in a checkerboard shape.

Each of the first memory cells 120 may include a first variable resistance pattern 127 and a first switching pattern 123. The first switching pattern 123 may be positioned adjacent to the row line 100, and the first variable resistance pattern 127 may be positioned adjacent to the column line 110. For example, the first variable resistance pattern 127 may be positioned adjacent to the first column line 110A. Specifically, when the first memory cell 120 is coupled to the row line 100 and the first column line 110A, the first switching pattern 123 may be positioned more adjacent to the row line 100 than the first variable resistance pattern 127, and the first variable resistance pattern 127 may be positioned more adjacent to the first column line 110A than the first switching pattern 123. Each of the first memory cells 120 may further include a first lower electrode pattern 121, a first intermediate electrode pattern 125 on the first lower electrode pattern 121, and a first upper electrode pattern 129 on the first intermediate electrode pattern 125. The first switching pattern 123 may be positioned between the first lower electrode pattern 121 and the first intermediate electrode pattern 125, and the first variable resistance pattern 127 may be positioned between the first intermediate electrode pattern 125 and the first upper electrode patterns 129.

In the first memory cell 120, the first lower electrode pattern 121, the first switching pattern 123, and the first intermediate electrode pattern 125 may configure a selection element. In addition, the first intermediate electrode pattern 125, the first variable resistance pattern 127, and the first upper electrode pattern 129 may configure a memory element. The memory element and the selection element may share the first intermediate electrode pattern 125. Here, the selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. The first switching pattern 123 may include at least one of arsenic (As), selenium (Se), sulfur (S), or tellurium (Te). Alternatively, the first switching pattern 123 may include a chalcogenide material. The first variable resistance pattern 127 may include a chalcogenide material. Alternatively, the first variable resistance pattern 127 may include at least one of antimony (Sb), silver (Ag), bismuth (Bi), or tellurium (Te).

Each of the second memory cells 130 may include a second variable resistance pattern 133 and a second switching pattern 137. The second variable resistance pattern 133 may be positioned adjacent to the row line 100, and the second switching pattern 137 may be positioned adjacent to the column line 110. For example, the second switching pattern 137 may be positioned adjacent to the second column line 110B. Specifically, when the second memory cell 130 is coupled to the row line 100 and the second column line 110B, the second variable resistance pattern 133 may be positioned more adjacent to the row line 100 than the second switching pattern 137, and the second switching pattern 137 may be positioned more adjacent to the second column line 110B than the second variable resistance pattern 133. Each of the second memory cells 130 may further include a second lower electrode pattern 131, a second intermediate electrode pattern 135 on the second lower electrode pattern 131, and a second upper electrode pattern 139 on the second intermediate electrode pattern 135. The second variable resistance pattern 133 may be positioned between the second lower electrode pattern 131 and the second intermediate electrode pattern 135, and the second switching pattern 137 may be positioned between the second intermediate electrode pattern 135 and the second upper electrode pattern 139.

In the second memory cell 130, the second lower electrode pattern 131, the first variable resistance pattern 133, and the second intermediate electrode pattern 135 may configure a memory element. In addition, the second intermediate electrode pattern 135, the second switching pattern 137, and the second upper electrode pattern 139 may configure a selection element. The second switching pattern 137 may include at least one of arsenic (As), selenium (Se), sulfur (S), or tellurium (Te). Alternatively, the second switching pattern 137 may include a chalcogenide material. The second variable resistance pattern 133 may include a chalcogenide material. Alternatively, the second variable resistance pattern 133 may include at least one of antimony (Sb), silver (Ag), bismuth (Bi), or tellurium (Te).

A width WV1 of the first variable resistance pattern 127 may be substantially equal to or different from a width WS1 of the first switching pattern 123. A width WV2 of the second variable resistance pattern 133 may be substantially equal to or different from a width WS2 of the second switching pattern 137. For example, the width WS1 of the first switching pattern 123 may be greater than the width WV1 of the first variable resistance pattern 127, and the width WV2 of the second variable resistance pattern 133 may be greater than the width WV2 of the second switching pattern 137. In addition, the width WV1 of the first variable resistance pattern 127 may be substantially equal to the width WS2 of the second switching pattern 137, and the width WS1 of the first switching pattern 123 may be substantially equal to the width WV2 of the second variable resistance pattern 133. For example, when the width WV1 of the first variable resistance pattern 127 may be substantially the same as the width WS2 of the second switching pattern 137, a difference between the width WV1 and the width WS2 may be not greater than 5%, 3%, 1%, 0.5%, 0.3%, or 0.1% of the average of the widths WV1 and WS2.

The first variable resistance pattern 127 of the first memory cell 120 may be positioned at substantially the same level as the second switching pattern 137 of the second memory cell 130. The second variable resistance pattern 133 of the second memory cell 130 may be positioned at substantially the same level as the first switching pattern 123 of the first memory cell 120. For example, when a level is measured from a top surface of the row line 100, at least one of a top surface or a bottom surface of the second variable resistance pattern 133 may be positioned at substantially the same level that of the first switching pattern 123, respectively, such that a level difference may be not greater than 5%, 3%, 1%, 0.5%, 0.3%, or 0.1% of the average levels of the top surfaces of the second variable resistance pattern 133 and the first switching pattern 123. In other words, the first variable resistance pattern 127 of the first memory cell 120 and the second variable resistance pattern 133 of the second memory cell 130 may be positioned in a diagonal direction. Here, the diagonal direction may refer to a direction crossing the first direction I and the second direction II.

During a set operation or a reset operation of the memory cells 120 and 130, heat may be generated in the variable resistance patterns 127 and 133. Heat may be generated as a phase of the variable resistance patterns 127 and 133 changes. According to embodiments of the present disclosure, the first memory cells 120 and the second memory cells 130 may be alternately arranged in the first direction I and the second direction II, and the first variable resistance pattern 127 of the first memory cell 120 and the second variable resistance pattern 133 of the second memory cell 130 may be positioned at different levels. In other words, the first variable resistance pattern 127 of the first memory cell 120 and the second variable resistance pattern 133 of the second memory cells 130 positioned around the first memory cell 120 may be positioned at a relatively long distance, compared to a conventional semiconductor device where variable resistance patterns of adjacent memory cells are positioned at the same level. Therefore, even though the heat generated in the first variable resistance pattern 127 is transferred to the peripheral second memory cells 130 in a semiconductor device according to embodiments of the present disclosure, loss of the data stored in the second variable resistance patterns 133 may be prevented or reduced, compared to the conventional semiconductor device.

The first liner layers 140 may extend in the first direction I and cover sidewalls of the memory cells 120 and 130. For example, a first pair of the first liner layers 140 may cover a pair of sidewalls of the first variable resistance pattern 127 of the first memory cell 120 that are adjacent in the second direction II, respectively. A second pair of the first liner layers 140 may cover a pair of sidewalls of the second switching pattern 137 of the second memory cell 130 that are adjacent in the second direction II, respectively.

The second liner layers 150 may extend in the first direction I and cover sidewalls of the memory cells 120 and 130. For example, a first pair of the second liner layers 150 may be positioned on the first pair of first liner layers 140 and may extend along a pair of sidewalls of the first switching pattern 123 that are adjacent in the second direction II. A second pair of the second liner layers 150 may be positioned on the second pair of the first liner layers 140 and may extend along a pair of sidewalls of the second variable resistance pattern 133 that are adjacent in the second direction II.

The third liner layers 170 may extend in the second direction II and cover sidewalls of the memory cells 120 and 130. For example, a first pair of the third liner layers 170 may cover a pair of sidewalls of the first variable resistance pattern 127 of the first memory cell 120 that are adjacent in the first direction I. A second pair of the third liner layers 170 may cover a pair of sidewalls of the second switching pattern 137 of the second memory cell 130 that are adjacent in the first direction I.

The fourth liner layers 180 may extend in the second direction II and cover sidewalls of the memory cells 120 and 130. For example, a first pair of the fourth liner layers 180 may be positioned on the first pair of the third liner layers 170 and may extend along a pair of sidewalls of the first switching pattern 123 that are adjacent in the first direction I. A second pair of the fourth liner layers 180 may be positioned on the second pair of the third liner layers 170 and may extend along a pair of sidewalls of the second variable resistance pattern 133 that are adjacent in the first direction I.

The liner layers 140, 150, 170, and 180 may not be removed in a manufacturing process and may remain on the sidewall of the memory cells 120 and 130 to protect the memory cells 120 and 130. When forming the switching patterns 123 and 137 by injecting ions (e.g., switching ions) selectively into one or more target regions of the memory cells 120 and 130 in the manufacturing process, the liner layers 140, 150, 170, and 180 may prevent or reduce injection of ions into other regions than the target regions. For example, in a process of forming the first switching pattern 123 of the first memory cell 120, the liner layers 140, 150, 170, and 180 may prevent or reduce injection of the switching ions to the first variable resistance pattern 127. In other words, because the double liner layers 140, 150, 170, and 180 together surround the sidewalls of the first variable resistance pattern 127, the liner layers 140, 150, 170, and 180 positioned on the sidewalls of the first variable resistance pattern 127 may be relatively thick compared to when liner layers (not shown) with a single layer structure surround the sidewalls of the first variable resistance pattern 127. Therefore, the injection of the switching ions into the first variable resistance pattern 127 may be prevented or reduced. The liner layers 140, 150, 170, and 180 may include an insulating material such as nitride or oxide.

The first gap fill layer 160 may be positioned between a first pair of the first memory cell 120 and the second memory cell 130 adjacent in the second direction II. The second gap fill layer 190 may be positioned between a second pair of the first memory cell 120 and the second memory cell 130 adjacent in the first direction I. One or both of the gap fill layers 160 and 190 may include at least one of carbide, nitride, or oxide.

According to the structure described above, the first memory cells 120 and the second memory cells 130 may be alternately arranged, and the first variable resistance pattern 127 of the first memory cell 120 and the second variable resistance pattern 133 of the second memory cell 130 may be positioned at a relatively long distance. Therefore, even though heat is generated in the memory cells 120 and 130 and transferred to the peripheral memory cells 120 and 130 during the set operation or the reset operation, loss of the data stored in the variable resistance patterns 127 and 133 of the memory cells 120 and 130 may be prevented or reduced.

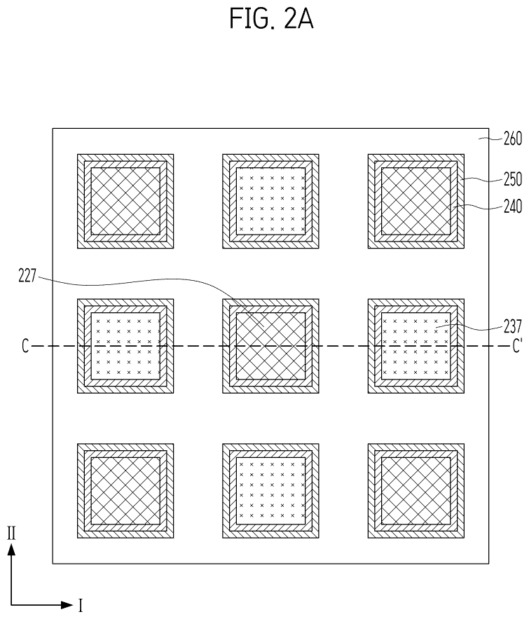

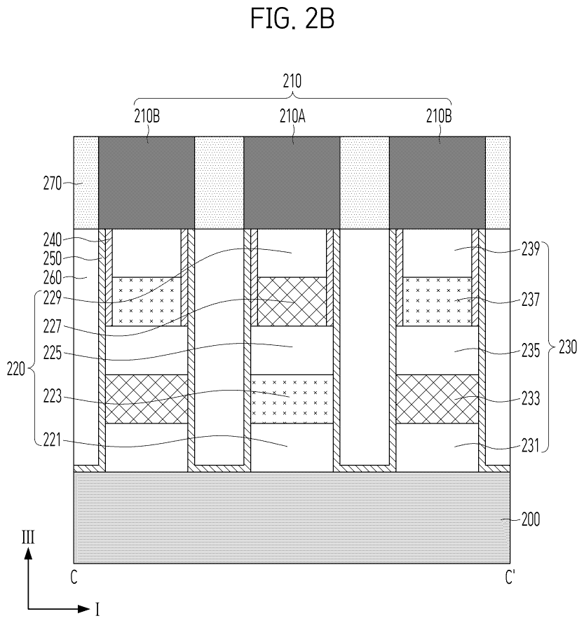

FIGS. 2A and 2B are diagrams illustrating a semiconductor device according to an embodiment of the present disclosure. FIG. 2A may be a plan view, and FIG. 2B may be a cross-sectional view taken along line C-C′ of FIG. 2A. Hereinafter, a content overlapping the content described above may be omitted for the interest of brevity.

Referring to FIGS. 2A and 2B, the semiconductor device may include row lines 200, column lines 210, first memory cells 220, second memory cells 230, first liner layers 240, second liner layers 250, or gap fill layers 260 and 270, or may include a combination thereof.

The row lines 200 may each extend in the first direction I and may be positioned to be spaced apart from each other in the second direction II crossing the first direction I. The column lines 210 may be positioned on the row lines 200 and may each extend in the second direction II crossing the row lines 200. The column lines 210 may include a first column line 210A or a second column line 210B. The first column line 210A may cross the row line 200, and the second column line 210B may cross the row line 200. The first column line 210A and the second column line 210B may be alternately arranged. Here, the row line 200 or the column line 210 may be a word line or a bit line. The row line 210 or the column line 210 may include a conductive material such as tungsten.

The first memory cells 220 and the second memory cells 230 may be positioned between the row lines 200 and the column lines 210. The first memory cell 220 may be positioned between the row line 200 and the first column line 210A, and the second memory cell 230 may be positioned between the row line 200 and the second column line 210B. The memory cells 220 and 230 may be alternately arranged in the first direction I and the second direction II. For example, the first memory cells 220 and the second memory cells 230 may be arranged in a checkerboard shape.

Each of the first memory cells 220 may include a first switching pattern 223 and a first variable resistance pattern 227. Each of the second memory cells 230 may include a second variable resistance pattern 233 and a second switching pattern 237. Each of the first memory cells 220 may further include a first lower electrode pattern 221, a first intermediate electrode pattern 225 on the first lower electrode pattern 221, and a first upper electrode pattern 229 on the first intermediate electrode pattern 225. Each of the second memory cells 230 may further include a second lower electrode pattern 231, a second intermediate electrode pattern 235 on the second lower electrode pattern 231, and a second upper electrode pattern 239 on the second intermediate electrode pattern 235. The first switching pattern 223 may be positioned between the first lower electrode pattern 221 and the first intermediate electrode pattern 225, and the first variable resistance pattern 227 may be positioned between the first intermediate electrode pattern 225 and the first upper electrode patterns 229. The second variable resistance pattern 233 may be positioned between the second lower electrode pattern 231 and the second intermediate electrode pattern 235, and the second switching pattern 237 may be positioned between the second intermediate electrode pattern 235 and the second upper electrode patterns 239.

The first switching pattern 223 may be positioned adjacent to the row line 200, and the first variable resistance pattern 227 may be positioned adjacent to the first column line 210A. The second variable resistance pattern 233 may be positioned adjacent to the row line 200, and the second switching pattern 237 may be positioned adjacent to the second column line 210B. The first variable resistance pattern 227 of the first memory cell 220 may be positioned at substantially the same level as the second switching pattern 237 of the second memory cell 230. The second variable resistance pattern 233 of the second memory cell 230 may be positioned at substantially the same level as the first switching pattern 223 of the first memory cell 220. The first variable resistance pattern 227 of the first memory cell 220 and the second variable resistance pattern 233 of the second memory cell 230 may be positioned in a diagonal direction. In other words, the first variable resistance pattern 227 of the first memory cell 220 and the second variable resistance pattern 233 of the second memory cells 230 positioned around the first memory cell 220 may be positioned at a relatively long distance compared to a conventional semiconductor device where variable resistance patterns of adjacent memory cells are positioned at the same level. Therefore, even though heat generated in the first variable resistance pattern 227 is transferred to the peripheral second memory cells 230, loss of data stored in the second variable resistance patterns 233 may be prevented or reduced, compared to the conventional semiconductor device.

A width of the first switching pattern 223 may be greater than a width of the first variable resistance pattern 227. A width of the second variable resistance pattern 233 may be greater than a width of the second switching pattern 237. In addition, the width of the first variable resistance pattern 227 may be substantially the same as the width of the second switching pattern 237, and the width of the first switching pattern 223 may be substantially the same as the width of the second variable resistance pattern 233. The first switching pattern 223 or the second switching pattern 237 may include at least one of arsenic (As), selenium (Se), sulfur (S), or tellurium (Te). The first variable resistance pattern 227 or the second variable resistance pattern 233 may include a chalcogenide material. Alternatively, the first variable resistance pattern 227 or the second variable resistance pattern 233 may include at least one of antimony (Sb), silver (Ag), bismuth (Bi), or tellurium (Te).

The first liner layers 240 may surround sidewalls of the memory cells 220 and 230. For example, the first liner layers 240 each may surround corresponding sidewalls of the first variable resistance patterns 227 of the first memory cells 220. The first liner layers 240 may surround sidewalls of the second switching patterns 237 of the second memory cells 230. The second liner layers 250 may surround sidewalls of the memory cells 220 and 230. For example, the second liner layers 250 may be positioned on the first liner layers 240 and may extend along sidewalls of the first switching patterns 223. The second liner layers 250 may be positioned on the first liner layers 240 and may extend along sidewalls of the second variable resistance patterns 233. The upper gap fill layers 270 may be positioned between the column lines 210A and 210B.

The liner layers 240 and 250 may not be removed in a manufacturing process and may remain on the sidewall of the memory cells 220 and 230 to protect the memory cells 220 and 230. For example, when forming the switching patterns 223 and 237 by injecting ions selectively into one or more target regions of the memory cells 220 and 230 in the manufacturing process, the liner layers 240 and 250 may prevent or reduce injection of ions (e.g., switching ions) into other regions than the target regions. In other words, because the double liner layers 240 and 250 surround the sidewalls of the first variable resistance pattern 227, the liner layers 240 and 250 positioned on the sidewalls of the first resistance pattern 227 may be relatively thick compared to when a single liner layer (not shown) surrounds the sidewalls of the first variable resistance pattern 227. Therefore, injection of the switching ions into the first variable resistance pattern 227 may be prevented or reduced. The liner layers 240 and 250 may include an insulating material such as nitride or oxide.

The gap fill layer 260 may be positioned between the memory cells 220 and 230. For example, the gap fill layer 260 may be positioned on the liner layers 240 and 250. The gap fill layers 260 and 190 may include at least one of carbide, nitride, or oxide.

According to the structure described above, the first variable resistance pattern 227 of the first memory cell 220 and the second variable resistance pattern 233 of the second memory cell 230 may be positioned at a relatively long distance. Therefore, even though heat is generated in the memory cells 220 and 230 and transferred to the peripheral memory cells 220 and 230 during the set operation or the reset operation, loss of the data stored in the variable resistance patterns 227 and 233 of the memory cells 220 and 230 may be prevented or reduced.

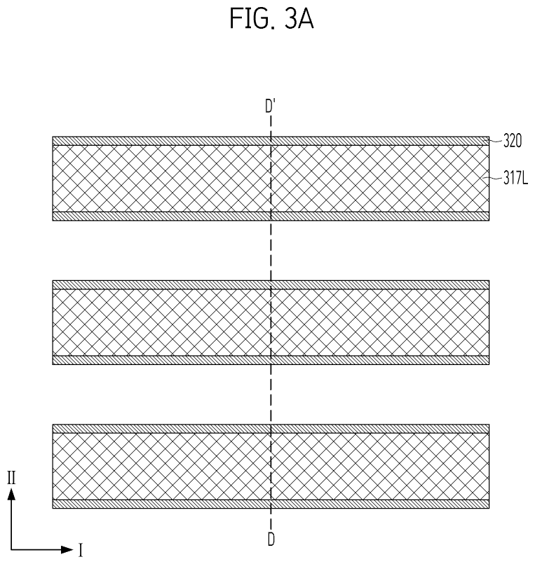

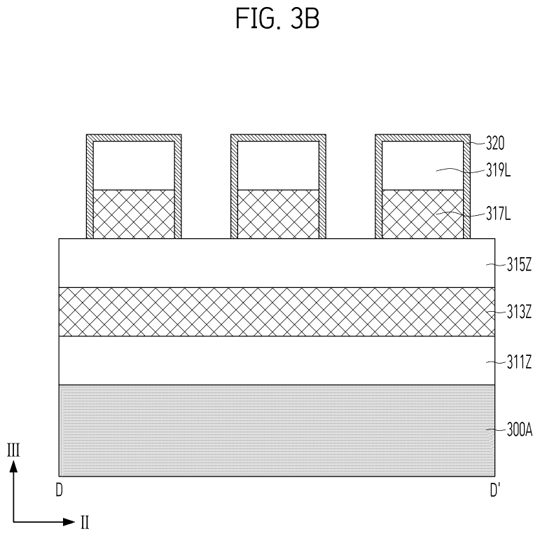

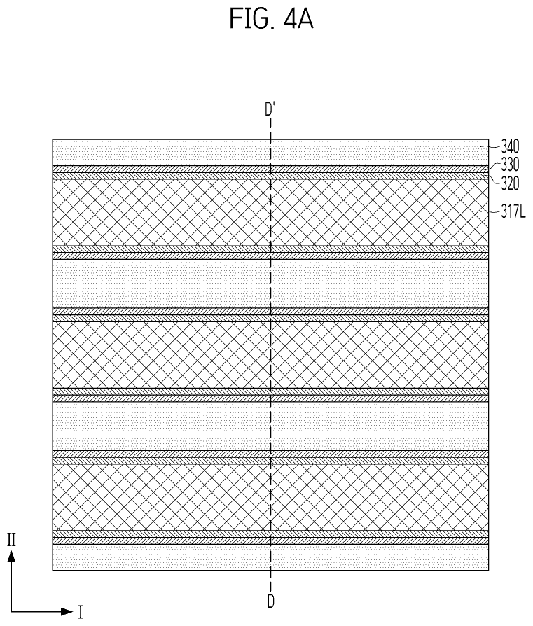

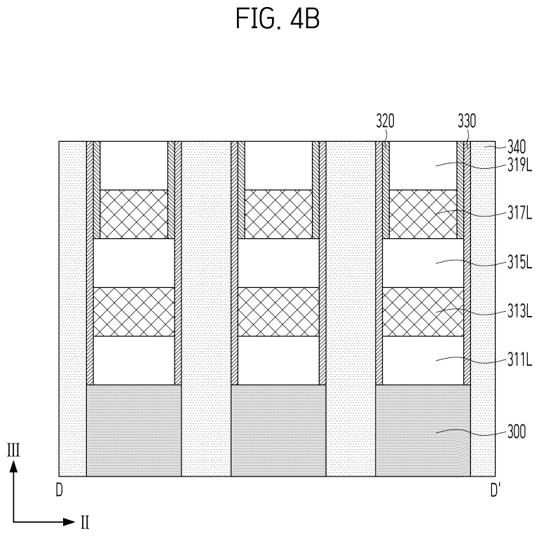

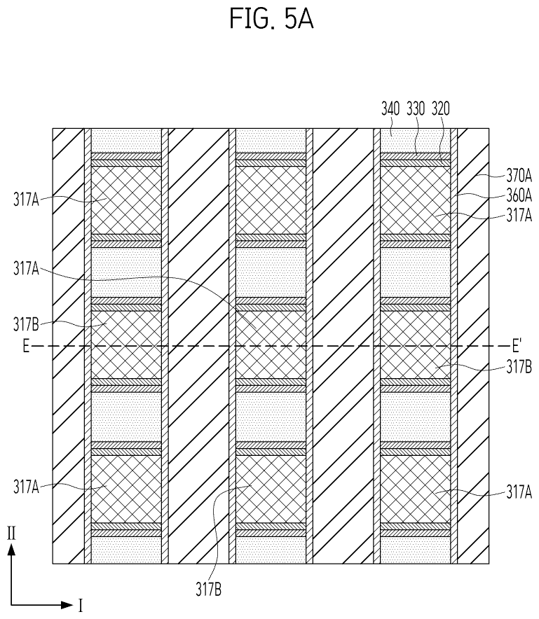

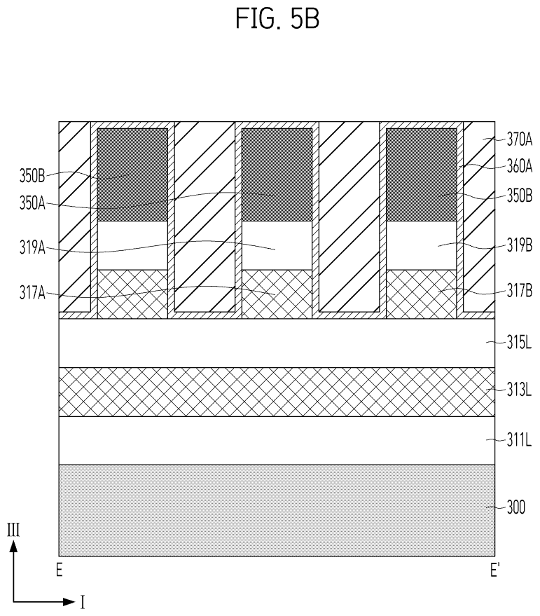

FIGS. 3A to 9B are diagrams illustrating a method of manufacturing a semiconductor device according to an embodiment of the present disclosure. FIGS. 3A, 4A, 5A, 6A, 7A, 8A, and 9A may be plan views, FIGS. 3B and 4B may be cross-sectional views taken along line D-D′ of FIGS. 3A and 4A, respectively, FIGS. 5B, 6B, 7B, 8B and 9B may be cross-sectional views taken along line E-E′ of FIGS. 5A, 6A, 7A, 8A, and 9A, respectively. Hereinafter, a content overlapping the content described above may be omitted for the interest of brevity.

Referring to FIGS. 3A and 3B, a lower conductive layer 300A may be formed. Here, the lower conductive layer 300A may include a conductive material such as tungsten. Subsequently, a lower electrode layer 311Z, a first variable resistance layer 313Z, an intermediate electrode layer 315Z, a second variable resistance layer, and an upper electrode layer may be sequentially formed on the conductive layer 300A. Subsequently, upper electrode lines 319L may be formed by etching the upper electrode layer. Here, the upper electrode lines 319L may each extend in the first direction I and may be spaced apart from each other in the second direction II crossing the first direction I. Subsequently, second variable resistance lines 317L may be formed by etching the second variable resistance layer. Here, the second variable resistance lines 317L may each extend in the first direction I and may be spaced apart from each other in the second direction II crossing the first direction I. Here, the lower electrode layer 311Z, the intermediate electrode layer 315Z, or the upper electrode line 319L may include metal, metal nitride, carbide, carbon nitride, or the like. The first variable resistance layer 313Z or the second variable resistance line 317L may include a chalcogenide material. The first variable resistance layer 313Z or the second variable resistance line 317L may include at least one of antimony (Sb), silver (Ag), bismuth (Bi), or tellium (Te).

Subsequently, a first liner layer 320 may be formed on the second variable resistance lines 317L. First, a preliminary first liner layer may be formed along a profile of the upper electrode lines 319L and the second variable resistance lines 317L extending in the first direction I. Subsequently, the intermediate electrode layer 315Z may be etched by etching lower portions of the preliminary first liner layer. In other words, the lower portions of the preliminary first liner layer each between adjacent second variable resistance lines 317L in the second direction II may be removed to expose corresponding portions of the intermediate electrode layer 315Z for subsequently etching the intermediate electrode layer 315Z. Here, the preliminary first liner layer may be separated into the first liner layers 320 as the lower portions of the preliminary first liner layer are etched. Therefore, the first liner layers 320 may surround sidewalls neighboring in the second direction II of each of the second variable resistance lines 317L. The first liner layer 320 may include an insulating material such as oxide or nitride.

Referring to FIGS. 4A and 4B, intermediate electrode lines 315L, first variable resistance lines 313L, and lower electrode lines 311L may be formed by sequentially etching the intermediate electrode layer 315Z, the first variable resistance layer 313Z, and the lower electrode layer 311Z. As etching proceeds in a state in which the first liner layer 320 is formed on sidewalls of the second variable resistance lines 317L, widths of the first variable resistance lines 313L and the second variable resistance lines 317L may be different. Subsequently, the intermediate electrode lines 315L, the first variable resistance lines 313L, and the lower electrode lines 311L may be exposed by sequentially etching the intermediate electrode layer 315Z, the first variable resistance layer 313Z, and the lower electrode layer 311Z so that a lower conductive layer 300A is exposed.

Subsequently, a second liner layer 330 may be formed on the first liner layer 320. First, a preliminary second liner layer may be formed on the first liner layer 320. For example, the preliminary second liner layer may be formed along a profile of the intermediate electrode lines 315L, the first variable resistance lines 313L, and the lower electrode lines 311L. Subsequently, the lower conductive layer 300A may be exposed by etching lower portions of the preliminary second liner layer. The preliminary second liner layer may be separated into the second liner layers 330 after the lower portions of the preliminary second liner layer are etched. Accordingly, the second liner layer 330 extending to the first variable resistance lines 313L may be formed on the first liner layer 320. The second liner layers 330 may surround sidewalls neighboring in the second direction II of each of the first variable resistance lines 313L. The second liner layer 330 may include an insulating material such as oxide or nitride.

Subsequently, lower conductive lines 300 may be formed by etching the lower conductive layer 300A. The lower conductive lines 300 may each extend in the first direction I and the lower conductive lines 300 may be spaced apart from each other in the second direction II. Here, the lower conductive lines 300 may be row lines. The row lines may be a word line or a bit line.

Subsequently, first gap fill layers 340 may be formed. For example, a preliminary first gap fill layer may be formed to fill a space between the second liner layers 330. Subsequently, the preliminary first gap fill layer may be planarized until upper surfaces of the upper electrode lines 319L are exposed. Accordingly, the first gap fill layer 340 may be formed on the second liner layer 330. In this process, the second liner layer 330 and the first liner layer 320 may also be planarized together with the preliminary first gap fill layer. Specifically, upper portions of the second liner layer 330 and the first liner layer 320 may be removed by planarization to form the second liner layer 330 and the first linear layer 320 as shown in FIG. 4B. Here, the first gap fill layer 340 may include at least one of carbide, nitride, or oxide.

Referring to FIGS. 5A and 5B, upper conductive lines 350A and 350B each extending in the second direction II may be formed. First, an upper conductive layer may be formed on the upper electrode lines 319L. Subsequently, upper conductive lines 350A and 350B extending in the second direction II and spaced apart in the first direction I may be formed by etching the upper conductive layer. Here, the upper conductive lines 350A and 350B may be column lines. The column lines may be a word line or a bit line. The upper conductive lines 350A and 350B may include a first column line 350A and a second column line 350B, respectively.

Subsequently, upper electrode patterns 319A and 319B and variable resistance patterns 317A and 317B may be formed by sequentially etching the upper electrode lines 319L and the second variable resistance lines 317L. Here, the upper electrode patterns 319A and 319B may be a first upper electrode pattern 319A and a second upper electrode pattern 319B, respectively. The variable resistance patterns 317A and 317B may be a first variable resistance pattern 317A and a second variable resistance pattern 317B, respectively. Here, the variable resistance patterns 317A and 317B may be alternately arranged in the first direction I and the second direction II.

Subsequently, a preliminary third liner layer 360A may be formed on the variable resistance patterns 317A and 318B. For example, the preliminary third liner layer 360A may be formed along a profile of the upper conductive lines 350A and 350B, the upper electrode patterns 319A and 319B, and the variable resistance patterns 317A and 317B. The preliminary third liner layer 360A may include an insulating material such as oxide or nitride.

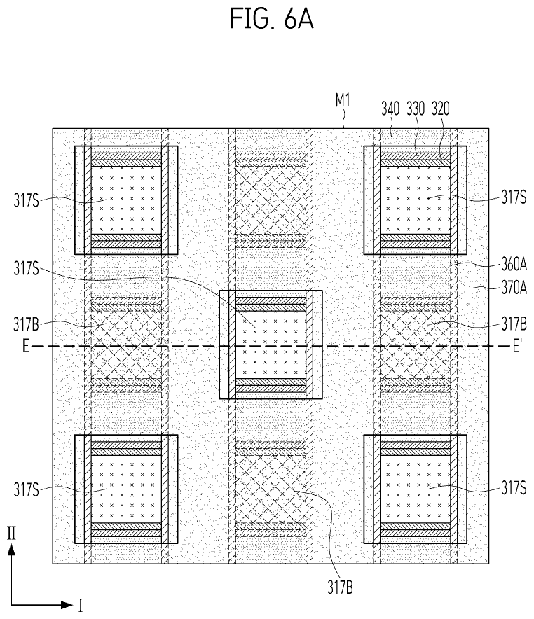

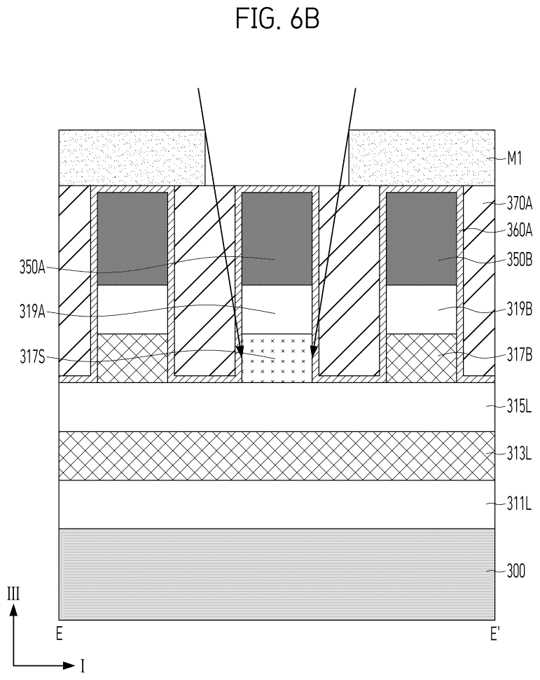

Subsequently, a first sacrificial gap fill layer 370A may be formed on the preliminary third liner layer 360A. For example, the first sacrificial gap fill layer 370A may be formed between the first variable resistance patterns 317A and the second variable resistance patterns 317B. In other words, the first sacrificial gap fill layer 370A may be formed to fill a space between the preliminary third liner layers 360A. The first sacrificial gap fill layer 370A may include at least one of carbide, nitride, or oxide. In an embodiment, the first sacrificial gap fill layer 370A may have characteristics desirable for penetration of ions therethrough as will be described below in more detail with reference to FIGS. 6A and 6B. For example, the first sacrificial gap fill layer 370A may include spin-on-carbon material.

Referring to FIGS. 6A and 6B, first switching patterns 317S may be formed. First, a first mask pattern M1 may be formed on the first sacrificial gap fill layer 370A. The first mask pattern M1 may expose the first variable resistance patterns 317A and may cover the second variable resistance patterns 317B. Specifically, the first mask pattern M1 may include openings over the first variable resistance patterns 317A and may cover the second variable resistance patterns 317B. For example, when seen in a plan view, the first mask pattern M1 may include openings within which the first variable resistance patterns 317A are disposed, respectively, and may overlap with the second variable resistance patterns 317B.

Subsequently, the first switching patterns 317S may be formed by injecting ions (e.g., switching ions) selectively into the first variable resistance patterns 317A. For example, the first switching patterns 317S may be formed by injecting the switching ions selectively into the first variable resistance patterns 317A using the first mask pattern M1 and the first sacrificial gap fill layer 370A. In other words, the first switching patterns 317S may be formed by injecting the switching ions selectively into the first variable resistance patterns 317A through the openings of the first mask pattern M1 and the first sacrificial gap fill layer 370A. Here, the switching ions may be injected selectively into the first variable resistance patterns 317A by adjusting an angle at which the switching ions are injected. For example, when an implantation tilt angle with respect to a vertical direction is smaller than a first angle, injected ions may reach lower portions of the preliminary third liner layer 360A between adjacent variable resistance patterns 317A and 317B. In contrast, when the implantation tilt angle is greater than a second angle, injected ions may reach regions above an upper surface of the first variable resistance pattern 317A. That is, the implantation tilt angle may be adjusted between the first angle and the second angle to make the injected ions reach the sidewalls of the first variable resistance pattern 317A to convert it to the first switching pattern 317S.

Subsequently, the first mask pattern M1 may be removed. Here, the switching ions may include ions of at least one of arsenic (As), selenium (Se), sulfur (S), or tellurium (Te).

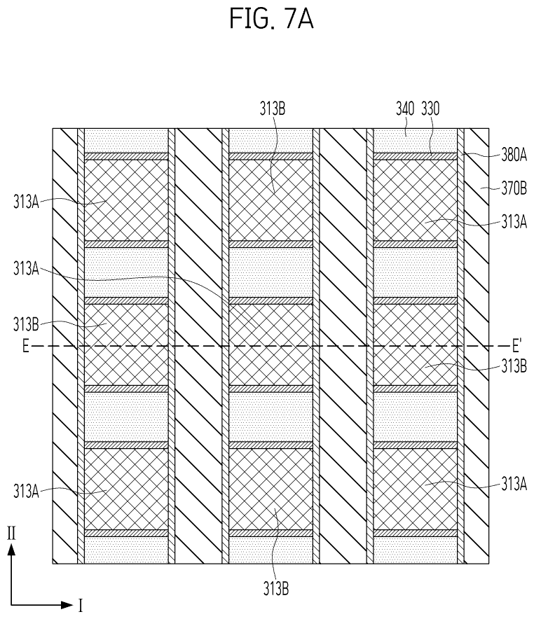

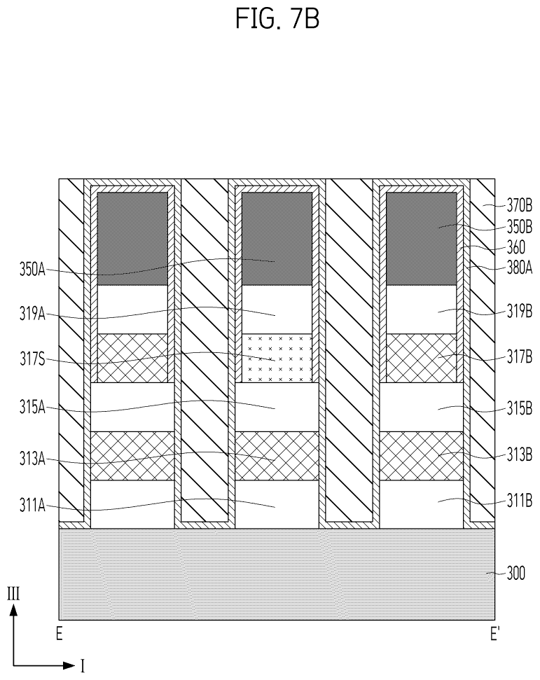

Referring to FIGS. 7A and 7B, intermediate electrode patterns 315A and 315B, variable resistance patterns 313A and 313B, and lower electrode patterns 311A and 311B may be formed by sequentially etching the intermediate electrode lines 315L, the first variable resistance lines 313L, and the lower electrode lines 311L. Here, the intermediate electrode patterns 315A and 315B may be a first intermediate electrode pattern 315A and a second intermediate electrode pattern 315B, respectively. The variable resistance patterns 313A and 313B may be a third variable resistance pattern 313A and a fourth variable resistance pattern 313B, respectively. The lower electrode patterns 311A and 311B may be a first lower electrode pattern 311A and a second lower electrode pattern 311B, respectively.

First, the first sacrificial gap fill layer 370A may be removed. Subsequently, the intermediate electrode lines 315L may be exposed by etching a lower surface of the preliminary third liner layer 360A. Here, the preliminary third liner layer 360A may be separated into third liner layers 360 as the lower portions of the preliminary third liner layer 360A are etched. Subsequently, the intermediate electrode lines 315L, the first variable resistance lines 313L, and the lower electrode lines 311L may be sequentially etched so that the lower conductive lines 300 are exposed. As etching proceeds in a state in which the third liner layers 360 are formed on sidewalls of the first switching patterns 317S and the second variable resistance patterns 317B, widths of the first switching patterns 317S and the second variable resistance patterns 317B, and the variable resistance patterns 313A and 313B may be different.

Subsequently, a preliminary fourth liner layer 380A may be formed on the third liner layer 360. For example, the preliminary fourth liner layer 380A may be formed along a profile of the intermediate electrode patterns 315A and 315B, the variable resistance lines 313A and 313B, and the lower electrode patterns 311A and 311B. The preliminary fourth liner layer 380A may include an insulating material such as oxide or nitride.

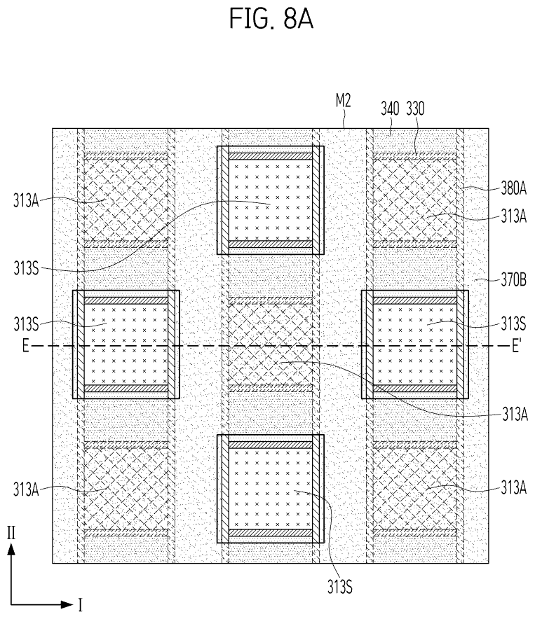

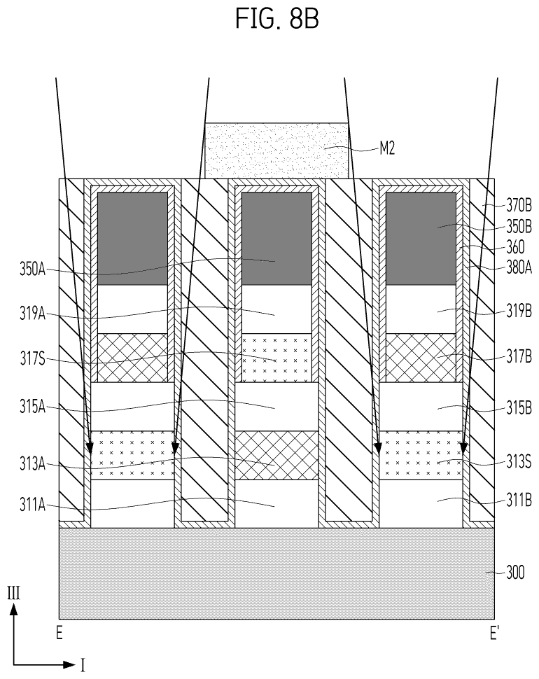

Subsequently, a second sacrificial gap fill layer 370B may be formed on the preliminary fourth liner layer 380A. For example, the second sacrificial gap fill layer 370B may be formed between the third variable resistance patterns 313A and the fourth variable resistance patterns 313B. In other words, the second sacrificial gap fill layer 370B may be formed to fill a space between the preliminary fourth liner layers 380A. The second sacrificial gap fill layer 370B may include at least one of carbide, nitride, or oxide. In an embodiment, the second sacrificial gap fill layer 370B may have characteristics desirable for penetration of ions therethrough as will be described below in more detail with reference to FIGS. 8A and 8B. For example, the second sacrificial gap fill layer 370B may include spin-on-carbon material.

Referring to FIGS. 8A and 8B, second switching patterns 313S may be formed. First, a second mask pattern M2 may be formed on the second sacrificial gap fill layer 370B. The second mask pattern M2 may cover the third variable resistance patterns 313A and may expose the fourth variable resistance patterns 313B. Specifically, the second mask pattern M2 may cover the third variable resistance patterns 313A and may include openings over the fourth variable resistance patterns 313B. For example, when seen in a plan view, the second mask pattern M2 may overlap with the third variable resistance patterns 313A and may include openings within which the fourth variable resistance patterns 313B are disposed, respectively. Subsequently, the second switching patterns 313S may be formed by injecting ions (e.g., switching ions) selectively into the fourth variable resistance patterns 313B. For example, the second switching patterns 313S may be formed by injecting the switching ions selectively into the fourth variable resistance patterns 313B using the second mask pattern M2 and the second sacrificial gap fill layer 370B. In other words, the second switching patterns 313S may be formed by injecting ions selectively into the fourth variable patterns 313B through the openings of the second mask pattern M2 and the second sacrificial gap fill layer 370B. Here, the switching ions may include ions of at least one of arsenic (As), selenium (Se), sulfur (S), or tellurium (Te). Subsequently, the second mask pattern M2 may be removed.

Because the second mask pattern M2 may be formed to cover the first switching patterns 317S, the second variable resistance patterns 317B may be exposed. Therefore, in a process of injecting the switching ions into the fourth variable resistance patterns 313B, some of the switching ions may be injected into the second variable resistance patterns 317B together. However, according to embodiments of the present disclosure, because the double liner layers 360 and 380A are formed on sidewalls of the second variable resistance patterns 317B, injection of the switching ions into the second variable resistance patterns 317B may be prevented or reduced. In addition, injection of the switching ions into the second variable resistance patterns 317B may be prevented or reduced by adjusting an angle at which the switching ions are injected. For example, when an implantation tilt angle with respect to a vertical direction is smaller than a first angle, injected ions may reach below a bottom surface of the second variable resistance pattern 313B. In contrast, when the implantation tilt angle is greater than a second angle, injected ions may reach above a top surface of the second variable resistance pattern 313B. That is, the implantation tilt angle may be adjusted between the first angle and the second angle to make the injected ions reach the sidewalls of the second variable resistance patterns 313B to convert it to the second switching pattern 313S.

The first lower electrode pattern 311A, the third variable resistance pattern 313A, the first intermediate electrode pattern 315A, the first switching pattern 317S, and the first upper electrode pattern 319A may configure a first memory cell. The second lower electrode pattern 311B, the second switching pattern 313S, the second intermediate electrode pattern 315B, the second variable resistance pattern 317B, and the second upper electrode pattern 319B may configure a second memory cell.

According to embodiments of the present disclosure, the third variable resistance pattern 313A of the first memory cell and the second variable resistance pattern 317B of the second memory cell may be formed at different levels. For example, the third variable resistance pattern 313A of the first memory cell and the second variable resistance patterns 317B of the second memory cells formed around the first memory cell may be formed at different levels and thus may be positioned at a relatively long distance. Therefore, even though heat is generated from the variable resistance patterns 313A and 317B and transferred to the peripheral memory cells during a set operation or a reset operation of the memory cells, loss of data stored in the variable resistance patterns 313A and 317B of the memory cells may be prevented or reduced.

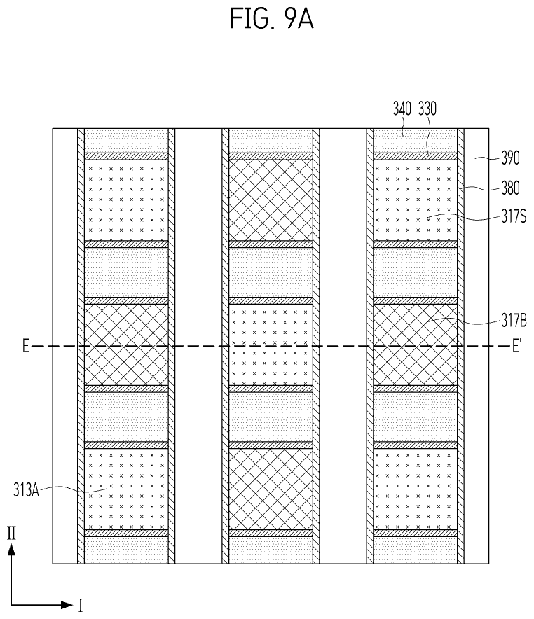

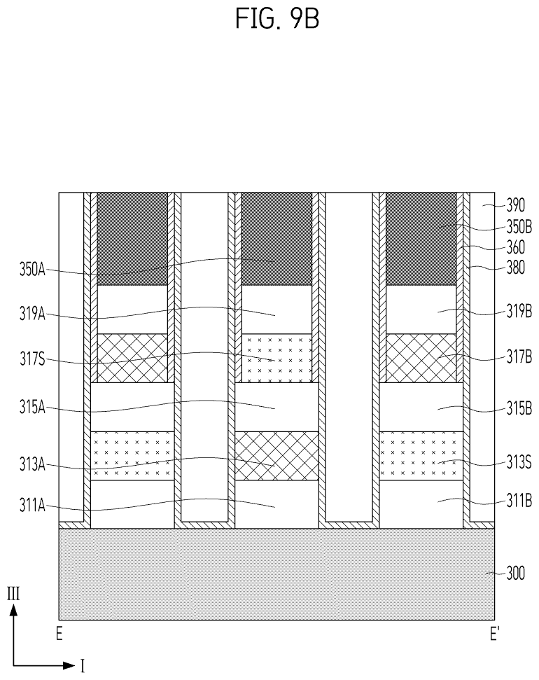

Referring to FIGS. 9A and 9B, the second sacrificial gap fill layer 370B may be removed. Subsequently, a preliminary second gap fill layer may be formed at a position where the second sacrificial gap fill layer 370B is removed. Subsequently, the preliminary second gap fill layer may be planarized until upper surfaces of the upper conductive lines 350A and 350B are exposed. Here, the preliminary second gap fill layer may be separated into second gap fill layers 390. In this process, the preliminary fourth liner layer 380A and the third liner layer 360 may also be planarized together with the preliminary second gap fill layer. Specifically, upper portions of the preliminary fourth liner layer 380A and the third liner layer 360 may be removed by planarization to form fourth liner layers 380 and third linear layers 360 as shown in FIG. 9B. Here, the preliminary fourth liner layer 380A may be separated into fourth liner layers 380. Accordingly, the second gap fill layer 390 may be formed on the fourth liner layer 380. The second gap fill layer 390 may include at least one of carbide, nitride, or oxide.

However, the second sacrificial gap fill layer 370B may be used as the second gap fill layer 390 without removing the second sacrificial gap fill layer 370B. In this case, after injecting switching ions through the second sacrificial gap fill layer 370B, the second sacrificial gap fill layer 370B, the preliminary fourth liner layer 380A, and the third liner layer 360 may be planarized until the upper surfaces of the upper conductive lines 350A and 350B are exposed.

According to an embodiment of the present disclosure, switching ions may be injected selectively into the first variable resistance pattern 317A, or the fourth variable resistance pattern 313B, or both. Here, the first switching pattern 317S and the second switching pattern 313S each may configure a selection element of each of the memory cells. The second variable resistance pattern 317B and the third variable resistance pattern 313A may configure a memory element of each of the memory cells. In this case, the second variable resistance pattern 317B, or the third variable resistance pattern 313A, or both may include at least one of antimony (Sb), silver (Ag), bismuth (Bi), or tellurium (Te).

However, embodiments of the disclosure are not limited thereto, and ions (e.g., memory ions) may also be injected into the variable resistance patterns 317A and 313B. For example, referring to FIGS. 3A and 3B again, the lower electrode layer 311Z, the first variable resistance layer 313Z, the intermediate electrode layer 315Z, the second variable resistance layer, and the upper electrode layer may be sequentially formed on the conductive layer 300A. Here, the first variable resistance layer 313Z and the second variable resistance layer may include switching ions. Therefore, the second variable resistance pattern 317B and the third variable resistance pattern 313A may configure a selection element of each of the memory cells as a switching pattern. In addition, the variable resistance patterns 317A and 313B may configure a memory element of each of the memory cells. Here, the second variable resistance pattern 317B and the third variable resistance pattern 313A may include at least one of arsenic (As), selenium (Se), sulfur (S), or tellurium (Te).

According to the manufacturing method described above, the first switching pattern 317S of the first memory cell and the second switching pattern 313S of the second memory cell may be selectively formed. The third variable resistance pattern 313A of the first memory cell and the second variable resistance patterns 317B of the second memory cells positioned around the first memory cell may be formed at different levels. Therefore, transfer of heat generated in the third variable resistance pattern 313A to the second variable resistance patterns 317B positioned nearby may be significantly reduced.

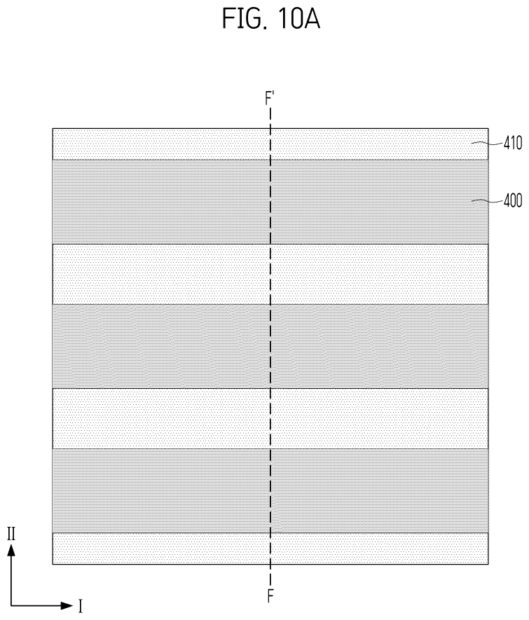

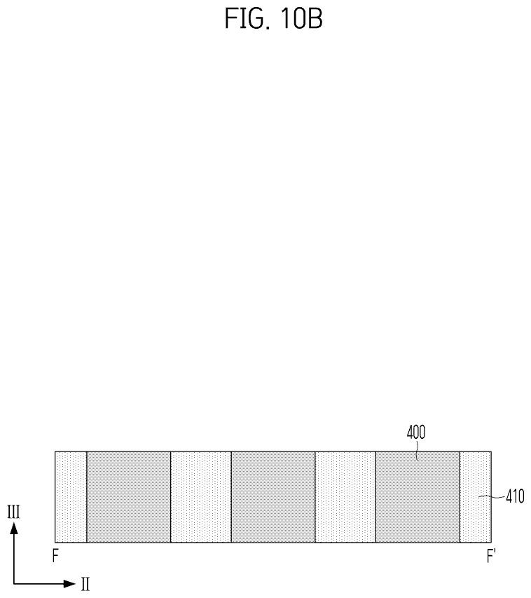

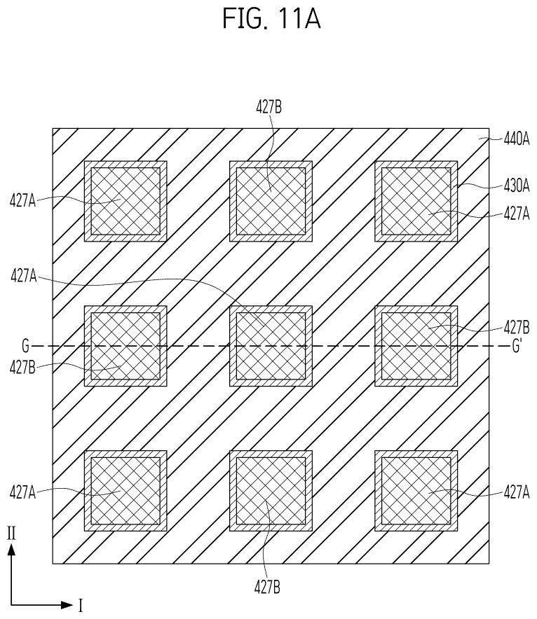

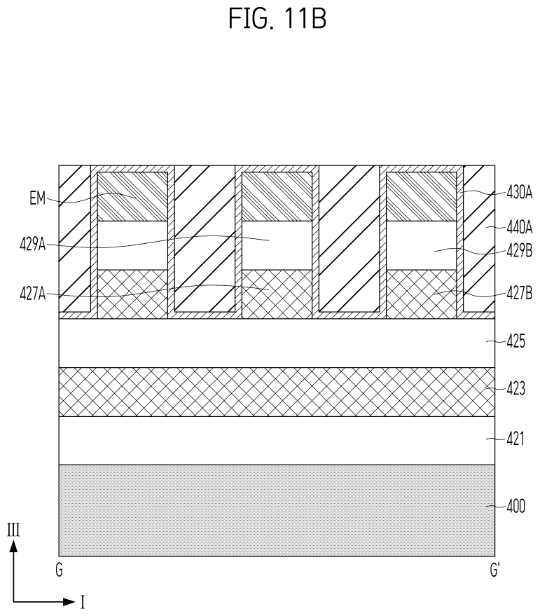

FIGS. 10A to 14B are diagrams illustrating a method of manufacturing a semiconductor device according to an embodiment of the present disclosure. FIGS. 10A, 11A, 12A, 13A, and 14A may be plan views, FIG. 10B may be a cross-sectional view taken along line F-F′ of FIG. 10A, and FIGS. 11B, 12B, 13B, and 14B may be cross-sectional views taken along line G-G′ of each FIG. A. Hereinafter, a content overlapping the content described above may be omitted for the interest of brevity.

Referring to FIGS. 10A and 10B, lower conductive lines 400 extending in the first direction I may be formed. The lower conductive lines 400 may be spaced apart in the second direction II crossing the first direction I. The lower conductive lines 400 may be a row line. The row line may be a word line or a bit line. Subsequently, lower gap fill layers 410 may be formed between the lower conductive lines 400. Here, the lower gap fill layers 410 may include at least one of carbide, nitride, or oxide.

Referring to FIGS. 11A and 11B, a lower electrode layer 421, a first variable resistance layer 423, an intermediate electrode layer 425, a second variable resistance layer, and an upper electrode layer may be sequentially stacked and formed on the lower conductive line 400. Subsequently, an etch mask pattern EM may be formed on the upper electrode layer. Here, the etch mask pattern EM may cover regions where memory cells are to be formed and expose remaining regions. Here, the regions where the memory cells are to be formed may be regions arranged in the first direction I and the second direction II. Subsequently, the intermediate electrode layer 425 may be exposed by etching the regions exposed by the etch mask pattern EM. For example, upper electrode patterns 429A and 429B and variable resistance patterns 427A and 427B may be formed by sequentially etching the upper electrode layer and the second variable resistance layer. Here, the upper electrode patterns 429A and 429B may be a first upper electrode pattern 429A and a second upper electrode pattern 429B, respectively. The variable resistance patterns 427A and 428B may be a first variable resistance pattern 427A and a second variable resistance pattern 427B, respectively.

Subsequently, a preliminary first liner layer 430A may be formed on the variable resistance patterns 427A and 427B. The preliminary first liner layer 430A may be formed along a profile of the etch mask pattern EM, the upper electrode patterns 429A and 429B, and the variable resistance patterns 427A and 427B. The preliminary first liner layer 430A may include an insulating material such as oxide or nitride.

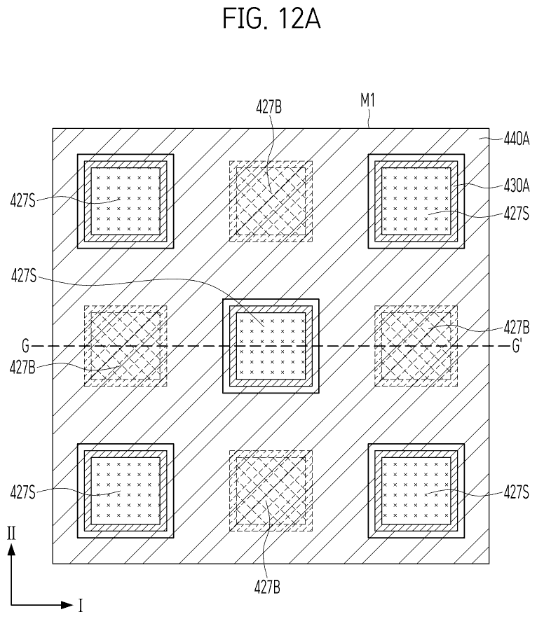

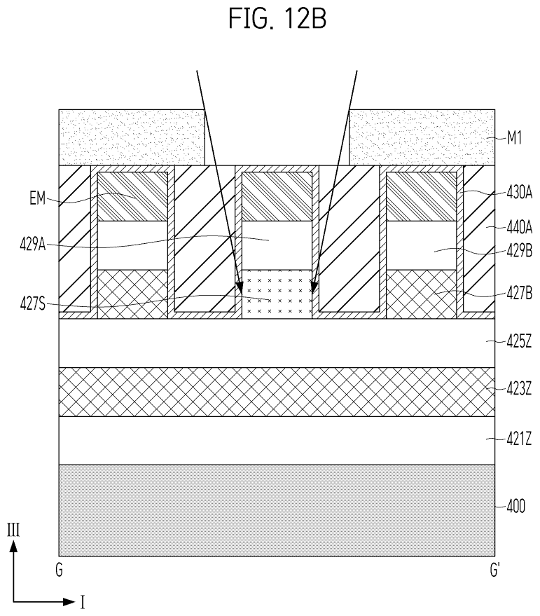

Subsequently, a first sacrificial gap fill layer 440A may be formed on the preliminary first liner layer 430A. The first sacrificial gap fill layer 440A may be formed to fill a space between the preliminary first liner layer 430A. The first sacrificial gap fill layer 440A may include at least one of carbide, nitride, or oxide. In an embodiment, the first sacrificial gap fill layer 440A may have characteristics desirable for penetration of ions therethrough as will be described below in more detail with reference to FIGS. 12A and 12B. For example, the first sacrificial gap fill layer 440A may include spin-on-carbon material.

Referring to FIGS. 12A and 12B, a first switching pattern 427S may be formed. First, a first mask pattern M1 may be formed on the first sacrificial gap fill layer 440A. The first mask pattern M1 may expose the first variable resistance patterns 427A and may cover the second variable resistance patterns 427B. Subsequently, the first switching patterns 427A may be formed by injecting a switching ion selectively into the first variable resistance patterns 427A using the first mask pattern M1 and the first sacrificial gap fill layer 440A. Here, the switching ions may include ions of at least one of arsenic (As), selenium (Se), sulfur (S), or tellurium (Te). Subsequently, the first mask pattern M1 may be removed. Subsequently, the first sacrificial gap fill layer 440A may be removed.

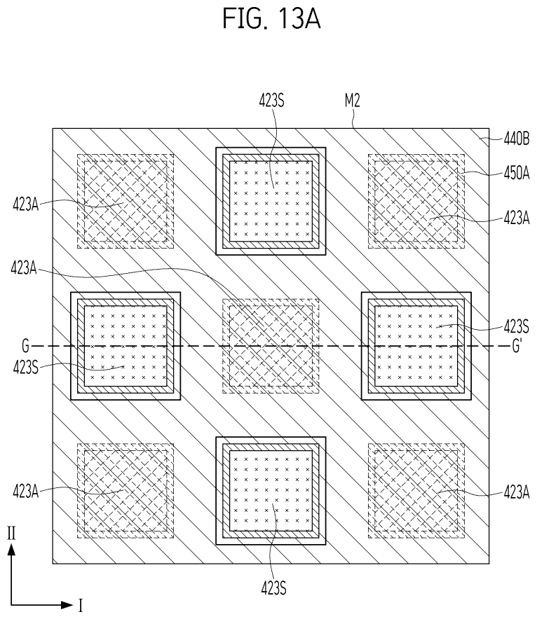

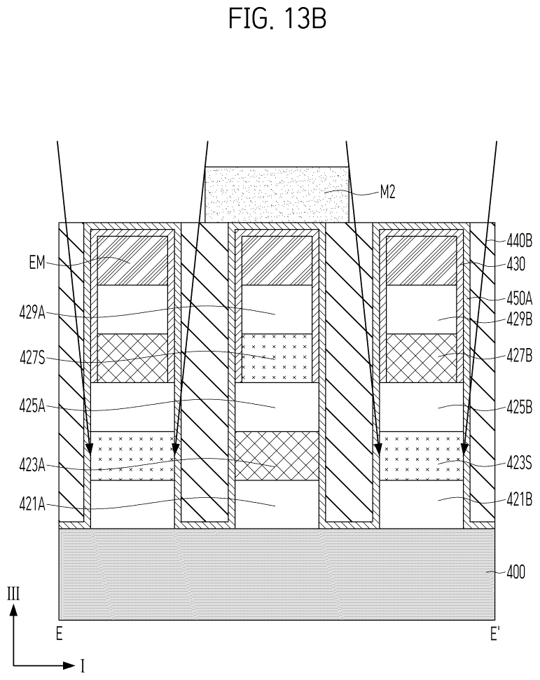

Referring to FIGS. 13A and 13B, intermediate electrode patterns 425A and 425B, variable resistance patterns 423A and 423B, and lower electrode patterns 421A and 421B may be formed by sequentially etching the intermediate electrode layer 425, the first variable resistance layer 423, and the lower electrode layer 421. Here, the intermediate electrode patterns 425A and 425B may be a first intermediate electrode pattern 425A and a second intermediate electrode pattern 425B, respectively. The variable resistance patterns 423A and 423B may be a third variable resistance pattern 423A and a fourth variable resistance pattern 423B, respectively. The lower electrode patterns 421A and 421B may be a first lower electrode pattern 421A and a second lower electrode pattern 421B, respectively.

The intermediate electrode layer 425 may be exposed by etching lower portions of the preliminary first liner layer 430A. In this process, the preliminary first liner layer 430A may be separated into first liner layers 430. Subsequently, intermediate electrode patterns 425A and 425B, variable resistance patterns 423A and 423B, and lower electrode patterns 421A and 421B may be formed by sequentially etching the intermediate electrode layer 425, the first variable resistance layer 423, and the lower electrode layer 421 so that the lower conductive lines 400 are exposed.

Subsequently, a preliminary second liner layer 450A may be formed on the first liner layer 430. For example, on the first liner layer 430, the preliminary second liner 450A may be formed along a profile of the intermediate electrode patterns 425A and 425B, the variable resistance patterns 423A and 423B, and the lower electrode patterns 421A and 421B.

Subsequently, second switching pattern 423S may be formed. First, a second sacrificial gap fill layer 440B may be formed on the preliminary second liner layer 450A. Subsequently, a second mask pattern M2 may be formed on the second sacrificial gap fill layer 440B. Here, the second mask pattern M2 may expose the fourth variable resistance patterns 423B and may cover the third variable resistance patterns 423A. Subsequently, the second switching patterns 423S may be formed by injecting ions (e.g., switching ions) selectively into the fourth variable resistance patterns 423B using the second mask pattern M2 and the second sacrificial gap fill layer 440B. Subsequently, the second mask pattern M2 may be removed. Subsequently, the second sacrificial gap fill layer 440B may be removed.

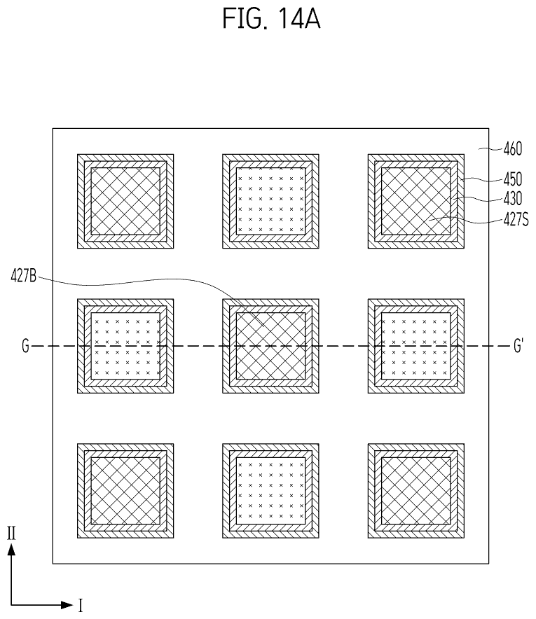

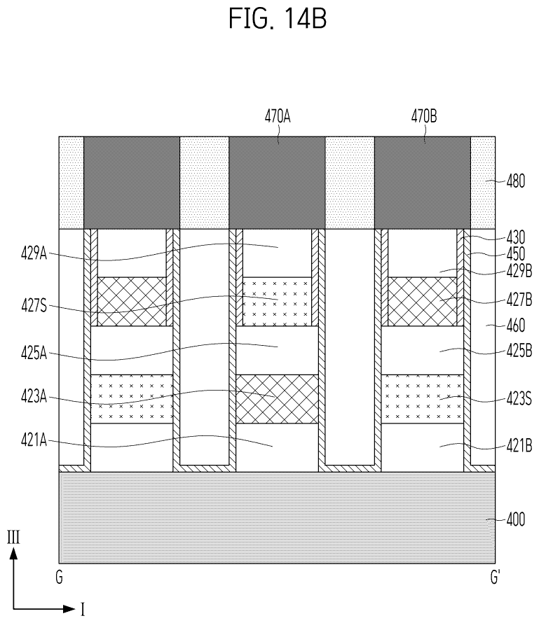

Referring to FIGS. 14A and 14B, a second gap fill layer 460 may be formed. For example, a preliminary second gap fill layer may be formed at a position where the second sacrificial gap fill layer 440B is removed. Subsequently, the preliminary second gap fill layer may be planarized until upper surfaces of the upper electrode patterns 429A and 429B are exposed. Here, the preliminary second gap fill layer may be separated into second gap fill layers 460. In this process, the preliminary second liner layer 450A, the first liner layer 430, and the etch mask pattern EM may also be planarized together with the preliminary second gap fill layer. Here, the etch mask pattern EM may be removed, and the preliminary second liner layer 450A may be separated into second liner layers 450. Accordingly, the second liner layer 450 may be formed on the first liner layer 430. The second gap fill layer 460 may include at least one of carbide, nitride, or oxide.

Subsequently, upper conductive lines 470A and 470B may be formed. First, an upper conductive layer may be formed on the upper electrode patterns 429A and 429B. Subsequently, the upper conductive lines 470A and 470B extending in the second direction II and spaced apart in the first direction I may be formed by etching the upper conductive layer so that the second gap fill layer 460 is exposed. Here, the upper conductive lines 470A and 470B may be a column line. The column line may be a word line or a bit line. Subsequently, upper gap fill layers 480 may be formed between the upper conductive lines 470A and 470B. Here, the upper gap fill layer 480 may include at least one of carbide, nitride, or oxide.

The first lower electrode pattern 421A, the third variable resistance pattern 423A, the first intermediate electrode pattern 425A, the first switching pattern 427S, and the first upper electrode pattern 429A may configure a first memory cell. The second lower electrode pattern 421B, the second switching pattern 423S, the second intermediate electrode pattern 425B, the second variable resistance pattern 427B, and the second upper electrode pattern 429B may configure a second memory cell.

According to the manufacturing method described above, the etch mask pattern EM may be formed considering regions where memory cells are to be formed. By forming the memory cells through a single etching process using the etch mask pattern EM, a process may be simplified compared to repeating a process of etching by dividing in the first direction I or the second direction II.

In addition, the first switching pattern 427S of the first memory cell and the second switching pattern 423S of the second memory cell may be selectively formed through the first mask pattern M1 or the second mask pattern M2.

Although some embodiments of the present disclosure have been described with reference to the accompanying drawings, various embodiments of the present disclosure are not limited to the above-described embodiments. Various forms of substitution, modification, and change of the embodiments may be possible by those skilled in the art to which the present disclosure belongs, and these also belong to the scope of the present disclosure.

What is claimed is:

1. A semiconductor device comprising:
a row line;
a first column line crossing the row line;
a second column line crossing the row line;
a first memory cell positioned between the row line and the first column line, and including a first variable resistance pattern adjacent to the first column line and a first switching pattern adjacent to the row line; and
a second memory cell positioned between the row line and the second column line, and including a second variable resistance pattern adjacent to the row line and a second switching pattern adjacent to the second column line.

2. The semiconductor device of claim 1, wherein the first switching pattern and the second variable resistance pattern are positioned at substantially the same level.

3. The semiconductor device of claim 1, wherein the second switching pattern and the first variable resistance pattern are positioned at substantially the same level.

4. The semiconductor device of claim 1, wherein the first memory cell further includes a first lower electrode pattern, a first intermediate electrode pattern on the first lower electrode pattern, and a first upper electrode pattern on the first intermediate electrode pattern, and the second memory cell further includes a second lower electrode pattern, a second intermediate electrode pattern on the second lower electrode pattern, and a second upper electrode pattern on the second intermediate electrode pattern.

5. The semiconductor device of claim 4, wherein the first switching pattern is positioned between the first lower electrode pattern and the first intermediate electrode pattern, and the first variable resistance pattern is positioned between the first intermediate electrode pattern and the first upper electrode pattern.

6. The semiconductor device of claim 4, wherein the second variable resistance pattern is positioned between the second lower electrode pattern and the second intermediate electrode pattern, and the second switching pattern is positioned between the second intermediate electrode pattern and the second upper electrode pattern.

7. The semiconductor device of claim 1, wherein a width of the first variable resistance pattern is substantially the same as a width of the second switching pattern, and a width of the second variable resistance pattern is substantially the same as a width of the first switching pattern.

8. The semiconductor device of claim 1, wherein a width of the first switching pattern is greater than a width of the first variable resistance pattern, and a width of the second variable resistance pattern is greater than a width of the second switching pattern.

9. The semiconductor device of claim 1, further comprising:
a pair of third liner layers covering a first pair of sidewalls of the first variable resistance pattern that are adjacent in a first direction;
a pair of fourth liner layers positioned on the pair of third liner layers and extending along a first pair of sidewalls of the first switching pattern that are adjacent in the first direction;
a pair of first liner layers covering a second pair of sidewalls of the first variable resistance pattern that are adjacent in a second direction crossing the first direction; and
a pair of second liner layers positioned on the pair of first liner layers and extending along a second pair of sidewalls of the first switching pattern that are adjacent in the second direction.

10. The semiconductor device of claim 9, wherein the pair of first liner layers are a first pair of first liner layers, and the pair of second liner layers are a first pair of second liner layers, the device further comprising:
a second pair of first liner layers covering a pair of sidewalls of the second switching pattern that are adjacent in the second direction; and
a second pair of second liner layers extending along a pair of sidewalls of the second variable resistance pattern that are adjacent in the second direction.

11. The semiconductor device of claim 9, wherein the pair of third liner layers are a first pair of third liner layers, and the pair of fourth liner layers are a first pair of fourth liner layers, the device further comprising:
a second pair of third liner layers covering a pair of sidewalls of the second switching pattern that are adjacent in the first direction; and
a second pair of fourth liner layers extending along a pair of sidewalls of the second variable resistance pattern that are adjacent in the first direction.

12. The semiconductor device of claim 1, wherein the first switching pattern, or the second switching pattern, or both include at least one of arsenic (As), selenium (Se), sulfur (S), or tellurium (Te).

13. A semiconductor device comprising:
row lines;
column lines crossing the row lines; and
memory cells positioned between the row lines and the column lines and including first memory cells and second memory cells,
wherein each of the first memory cells includes a first variable resistance pattern and a first switching pattern on the first variable resistance pattern, and
wherein each of the second memory cells includes a second switching pattern and a second variable resistance pattern on the second switching pattern.

14. The semiconductor device of claim 13, wherein the first memory cells and the second memory cells are alternately arranged in a first direction and a second direction crossing the first direction.

15. The semiconductor device of claim 13, wherein the first switching pattern and the second variable resistance pattern are positioned at substantially the same level.

16. The semiconductor device of claim 13, wherein the second switching pattern and the first variable resistance pattern are positioned at substantially the same level.

17. The semiconductor device of claim 13, further comprising:
a second gap fill layer positioned between a first one of the first memory cells and a first one of the second memory cells that are adjacent in a first direction; and
a first gap fill layer positioned between a second one of the first memory cells and a second one of the second memory cells that are adjacent in a second direction crossing the first direction.

18. The semiconductor device of claim 17, wherein the first gap fill layer, or the second gap fill layer, or both include at least one of carbide, nitride, or oxide.

19. A method of manufacturing a semiconductor device, the method comprising:
forming first variable resistance patterns and second variable resistance patterns alternately arranged along a first direction and a second direction crossing the first direction;
forming a first mask pattern that covers the second variable resistance patterns and includes openings over the first variable resistance patterns; and
forming first switching patterns by injecting ions selectively into the first variable resistance patterns.

20. The method of claim 19, wherein forming the first switching patterns comprises:
forming a first sacrificial gap fill layer between the first variable resistance patterns and the second variable resistance patterns; and
forming the first switching patterns by injecting the ions into the first variable resistance patterns through the openings of the first mask pattern and the first sacrificial gap fill layer,
wherein the first mask pattern is formed on the first sacrificial gap fill layer.

21. The method of claim 20, further comprising:
forming third variable resistance patterns positioned under the first switching patterns and fourth variable resistance patterns positioned under the second variable resistance patterns;
forming a second mask pattern that covers the third variable resistance patterns and includes openings over the fourth variable resistance patterns; and
forming second switching patterns by injecting the ions selectively into the fourth variable resistance patterns.

22. The method of claim 21, wherein forming the second switching patterns comprises:
forming a second sacrificial gap fill layer between the third variable resistance patterns and the fourth variable resistance patterns; and
forming the second switching patterns by injecting the ions selectively into the fourth variable resistance patterns through the openings of the second mask pattern and the second sacrificial gap fill layer,
wherein the second mask pattern is formed on the second sacrificial gap fill layer.

23. The method of claim 19, wherein the ions include at least one of arsenic (As), selenium (Se), sulfur (S), or tellurium (Te).

24. A method of manufacturing a semiconductor layer, the method comprising:
forming a first variable resistance layer;
forming a second variable resistance layer on the first variable resistance layer;
forming second variable resistance lines by etching the second variable resistance layer;
forming first variable resistance lines by etching the first variable resistance layer;
forming first variable resistance patterns and second variable resistance patterns that are alternately arranged in a first direction and a second direction crossing the first direction, by etching the second variable resistance lines;
forming first switching patterns by injecting ions selectively into the second variable resistance patterns;
forming third variable resistance patterns and fourth variable resistance patterns by etching the first variable resistance lines; and
forming second switching patterns by injecting the ions selectively into the third variable resistance patterns.

25. The method of claim 24, wherein forming the first switching patterns comprises:
forming a first sacrificial gap fill layer between the first variable resistance patterns and the second variable resistance patterns;
forming a first mask pattern that covers the first variable resistance patterns and includes openings over the second variable resistance patterns; and
forming the first switching patterns by injecting the ions into the second variable resistance patterns through the openings of the first mask pattern through the first sacrificial gap fill layer.

26. The method of claim 24, wherein forming the second switching patterns comprises:
forming a second sacrificial gap fill layer between the third variable resistance patterns and the fourth variable resistance patterns;
forming a second mask pattern including openings over the third variable resistance patterns and covering the fourth variable resistance patterns; and
forming the second switching patterns by injecting the ions into the third variable resistance patterns through the openings of the second mask pattern and the second sacrificial gap fill layer.

27. The method of claim 24, further comprising:
forming a first liner layer on the second variable resistance lines, before forming the first variable resistance lines.

28. The method of claim 27, further comprising:
forming a second liner layer that extends to the first variable resistance lines on the first liner layer.

29. The method of claim 28, further comprising:
forming a first gap fill layer on the second liner layer.

30. The method of claim 29, wherein the first gap fill layer includes at least one of carbide, nitride, or oxide.

31. The method of claim 24, further comprising:
forming a third liner layer on the second variable resistance patterns, before forming the second switching patterns.

32. The method of claim 31, further comprising:
forming a fourth liner layer that extends to the first variable resistance patterns on the third liner layer.

33. The method of claim 32, further comprising:
forming a second gap fill layer on the fourth liner layer.

34. The method of claim 33, wherein the second gap fill layer includes at least one of carbide, nitride, or oxide.

35. The method of claim 24, wherein the ions include ions of at least one of arsenic (As), selenium (Se), sulfur (S), or tellurium (Te).
